(19) United States
(12) Patent Application Publication
(10) Pub. No.: US 2009/0242031 A1
(43) Pub. Date: Oct. 1, 2009

(54) Photovoltaic Assembly Including a Conductive Layer Between a Semiconductor Lamina and a Receiver Element

(75) Inventors: S. Brad Herner, San Jose, CA (US); Aditya Agarwal, Sunnyvale, CA (US)

Correspondence Address: THE MUELLER LAW OFFICE, P.C., 12951 Harwick Lane, San Diego, CA, 92130, US

(73) Assignee: Twin Creeks Technologies, Inc., Santa Clara, CA (US)

(21) Appl. No.: 12/057,274

(22) Filed: Mar. 27, 2008

(51) Int. Cl. H01L 31/028; H01L 31/04; H01L 21/18

(52) U.S. Cl. 136/261; 136/252; 438/92; 438/64; 257/E21.088; 257/E21.359

(57) ABSTRACT

A semiconductor donor body is affixed to a receiver element, and a thin semiconductor lamina is cleaved from the donor body, remaining affixed to the receiver element. A photovoltaic assembly is fabricated which includes the lamina and the receiver element, wherein a photovoltaic cell comprises the lamina. The bond between the semiconductor donor body and the receiver element must survive processing to complete the cell, as well as eventual assembly, transport, and operation in a finished photovoltaic module. It has been found that inclusion of a conductive layer such as titanium or aluminum aids bonding between the semiconductor donor body and the receiver element. In some embodiments, the conductive layer may also serve as an electrical contact and/or as a reflective layer.

### RELATED APPLICATIONS

This application is related to Herner, U.S. patent application Ser. No. ______, “Method to Form a Photovoltaic Cell Comprising a Thin Lamina Bonded to a Discrete Receiver Element,” (attorney docket number TCA-002) filed on even date herewith and hereby incorporated by reference.

### BACKGROUND OF THE INVENTION

The invention relates to a photovoltaic assembly comprising a semiconductor lamina bonded to a receiver element.

Photovoltaic cells are most often formed of silicon. The volume of silicon in the photovoltaic cell is often the largest cost item of the cell; thus methods to reduce consumption of silicon will serve to reduce cost.

If methods to form photovoltaic cells require bonding of wafers, it is advantageous if such methods do not require excessive heat, pressure, or plasma treatments, as these complicate fabrication and add cost.

A method to form a photovoltaic cell that minimizes use of silicon and simplifies processing would be advantageous.

### SUMMARY OF THE PREFERRED EMBODIMENTS

The present invention is defined by the following claims, and nothing in this section should be taken as a limitation on those claims. In general, the invention is directed to a photovoltaic assembly comprising a semiconductor lamina, a receiver element, and a conductive layer disposed between the two. A photovoltaic module can be formed comprising a plurality of such photovoltaic assemblies.

A first aspect of the invention provides for a photovoltaic assembly comprising: a semiconductor lamina having a lamina widest dimension; a receiver element having a receiver widest dimension, wherein the receiver widest dimension does not exceed the lamina widest dimension by more than about 50 percent; a continuous or discontinuous layer of conductive material disposed between the semiconductor lamina and the receiver; and a photovoltaic cell, wherein the photovoltaic cell comprises the semiconductor lamina.

Another aspect of the invention provides for a method for forming a photovoltaic cell, the method comprising: affixing a first surface of a semiconductor donor body to a receiving surface of a receiver element wherein a conductive layer is disposed between the first surface and the receiving surface, wherein the semiconductor donor body has a donor widest dimension, and the receiver element has a receiver widest dimension, wherein the receiver widest dimension does not exceed the donor widest dimension by more than fifty percent; and cleaving a semiconductor lamina from the semiconductor donor body at a cleave plane wherein the semiconductor lamina remains affixed to the receiver element, wherein the photovoltaic cell comprises the semiconductor lamina.

An embodiment of the invention provides for a method for forming a photovoltaic assembly comprising a photovoltaic cell, the method comprising: implanting one or more species of gas ions through a first surface of a semiconductor donor body to define a cleave plane; affixing the first surface of the semiconductor donor body to a receiving surface of a receiver element, wherein the first surface of the semiconductor donor body is in immediate contact with a conductive layer, wherein the semiconductor donor body has a donor widest dimension, and the receiver element has a receiver widest dimension, wherein the receiver widest dimension does not exceed the donor widest dimension by more than fifty percent; cleaving a semiconductor lamina from the semiconductor donor body, wherein the semiconductor lamina remains affixed to the receiver element; and fabricating the photovoltaic cell, wherein the photovoltaic cell comprises the semiconductor lamina, and wherein the photovoltaic assembly comprises the receiver element and the semiconductor lamina.

Another aspect of the invention provides for a photovoltaic assembly comprising: a semiconductor lamina having a lamina widest dimension; a receiver element having a receiver widest dimension, wherein the receiver widest dimension does not exceed the lamina widest dimension by more than about 50 percent; a layer of metal, metal compound, metal alloy, or metal silicide disposed between the semiconductor lamina and the receiver; and a photovoltaic cell, wherein the photovoltaic cell comprises the semiconductor lamina.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view of a prior art photovoltaic cell.

FIGS. 2a-2d are cross-sectional views illustrating stages in formation of an embodiment of Sivaram et al., U.S. patent application Ser. No. 12/026,530.

FIG. 3 is a plan view of a photovoltaic module formed according to an embodiment of Sivaram et al.

FIG. 4 is a cross-sectional view of an embodiment of the present invention having a photovoltaic assembly affixed to a module substrate.

FIGS. 5a and 5b are cross-sectional views of embodiments of the present invention having a photovoltaic assembly affixed to a module superstrate.

FIGS. 6a-6d are cross-sectional views illustrating stages in fabrication of an embodiment of the present invention.

FIGS. 7a-7c are cross-sectional views illustrating stages in fabrication of another embodiment of the present invention.

FIGS. 8a and 8b are cross-sectional views illustrating stages in formation of still another embodiment of the present invention.

FIGS. 9a and 9b are cross-sectional views illustrating stages in formation of a different embodiment of the present invention.

FIGS. 10 and 10b are cross-sectional views illustrating stages in formation of an embodiment of the present invention in which a photovoltaic assembly is affixed to a superstrate.

### DETAILED DESCRIPTION OF THE PREFERRED EMBODIMENTS

A conventional photovoltaic cell is formed in a substantially crystalline silicon wafer, which may be monocrystalline, multicrystalline, polycrystalline, or microcrystalline. The photovoltaic cell is affixed to a substrate or superstrate, connected electrically in series with other photovoltaic cells, forming a photovoltaic module.

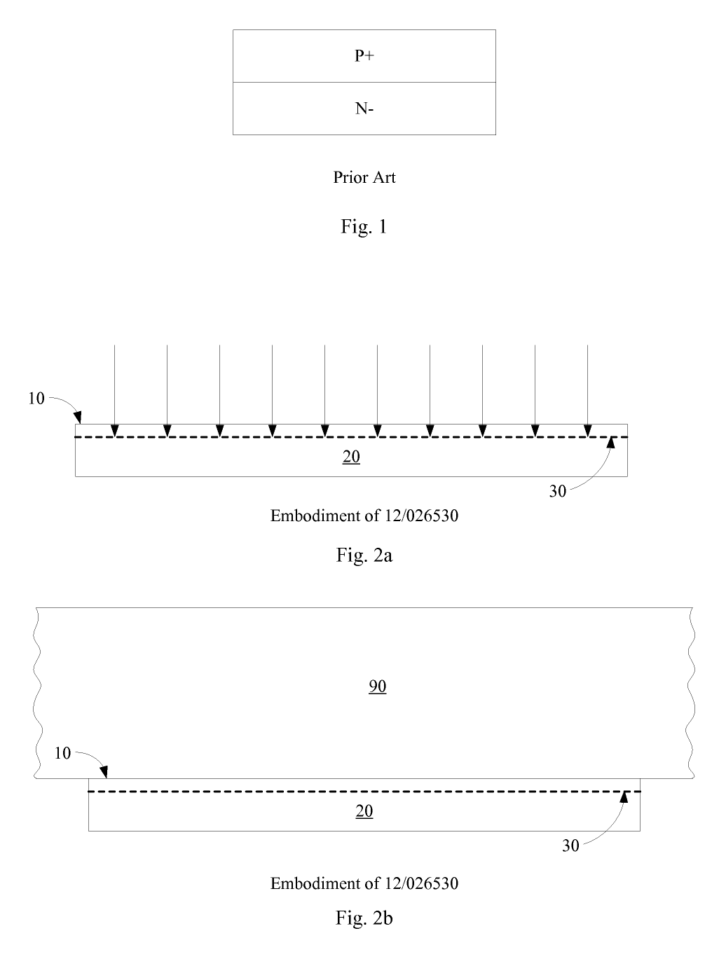

A conventional prior art photovoltaic cell includes a p-n diode; an example is shown in FIG. 1. A depletion zone forms at the p-n junction, creating an electric field. Incident photons will knock electrons from the conduction band to the valence band, creating electron-hole pairs. Within the electric field at the p-n junction, electrons tend to migrate toward the n region of the diode, while holes migrate toward the p region, resulting in current. This current can be called the photocurrent. Typically the dopant concentration of one region will be higher than that of the other, so the junction is either a p+/n− junction (as shown in FIG. 1) or a p−/n+junction. The more lightly doped region is known as the base of the photovoltaic cell, while the more heavily doped region is known as the emitter. Most carriers are generated within the base, and it is typically the thickest portion of the cell. The base and emitter together form the active region of the cell.

A silicon wafer is typically about 200 to 300 microns thick. Silicon photovoltaic cells need not be this thick to be effective or commercially useful. A large portion of the cost of conventional photovoltaic cells is the cost of silicon feedstock, so decreasing the thickness of a photovoltaic cell may reduce cost. It is known to slice silicon wafers as thin as about 180 microns, but such wafers are fragile and prone to breakage. Methods to form a variety of thin photovoltaic cells, having a thickness of 100 microns or less, for example between about 1 and about 50 microns, in some embodiments between about 2 and about 20 microns, are disclosed in Sivaram et al., U.S. patent application Ser. No. 12/026,530, “Method to Form a Photovoltaic Cell Comprising a Thin Lamina,” filed Feb. 5, 2008, hereby incorporated by reference.

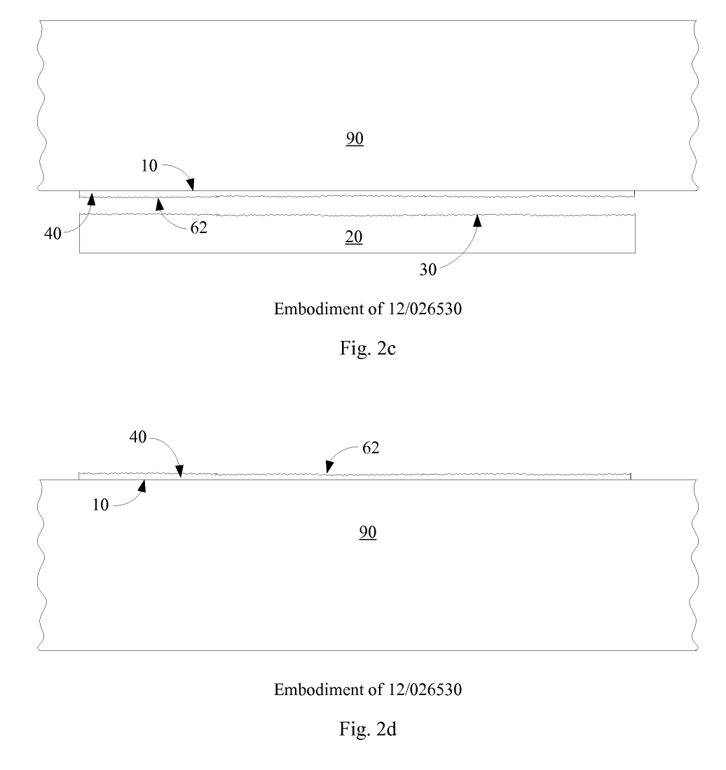

Referring to FIG. 2a, in embodiments of Sivaram et al., a semiconductor donor wafer 20 is implanted with one or more species of gas ions, for example hydrogen or helium ions. The implanted ions define a cleave plane 30 within the semiconductor donor wafer. As shown in FIG. 2b, donor wafer 20 is affixed at first surface 10 to receiver 90. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 50 microns thick, in some embodiments between about 1 and about 10 microns thick. FIG. 2d shows the structure inverted, with substrate 90 at the bottom, as during operation.

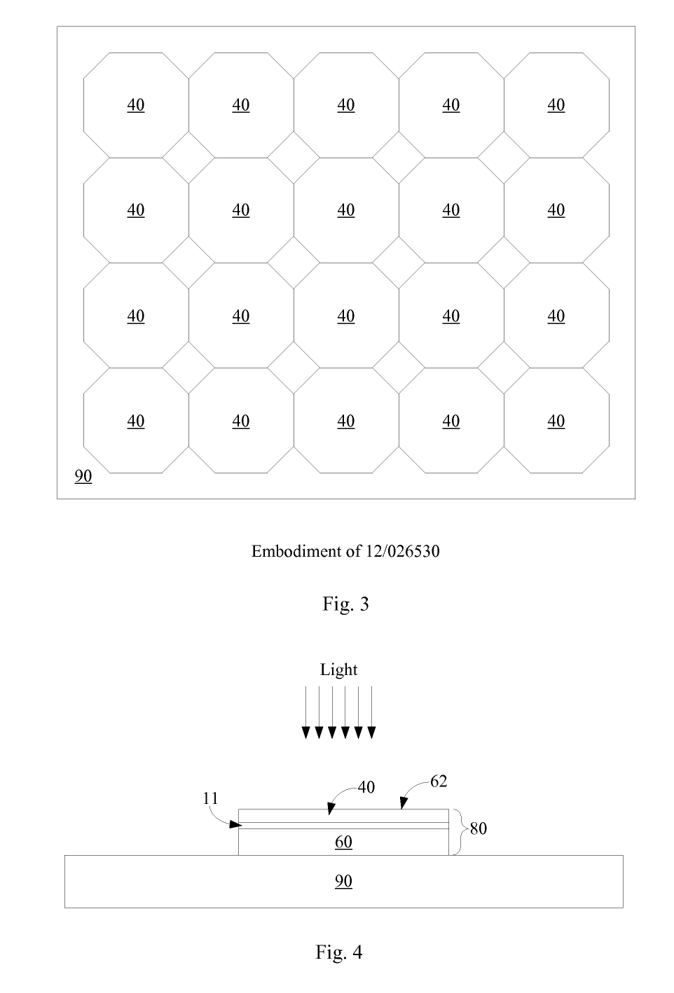

As described in Sivaram et al. and shown in FIG. 3, in some embodiments, receiver 90 can be the final substrate or superstrate which will support the photovoltaic module; for example it may be a meter or more wide, and may have 12, 36, or more semiconductor laminae 40 arrayed side-by-side.

Alternatively, as described in Herner, filed on even date herewith, a photovoltaic assembly is conveniently formed by affixing the semiconductor donor body to a discrete receiver element which is preferably about the same size, and perhaps about the same shape, as the semiconductor donor body. The receiver element may or may not be about the size of a conventional silicon wafer, and can also be referred to as a receiver wafer. Additional processing is performed on this discrete assembly, which may be wafer-sized. The smaller size allows for fabrication to be performed on standard wafer-handling equipment, and further allows for completed cells to be tested and sorted according to conversion efficiency. After testing and sorting, cells with similar conversion efficiencies can be grouped together for inclusion in a photovoltaic module.

The semiconductor donor body and the receiver wafer must be adhered such that the bond between them will survive subsequent processing, including heat and mechanical stress, without delaminating.

Wafer bonding techniques are well-known. In formation of a silicon-on-insulator wafer, for example, it is common to bond a silicon wafer to a silicon dioxide wafer. Bonding these wafers securely may require high heat, high pressure, or plasma or other treatments of the surfaces to be bonded.

In embodiments of the present invention, a semiconductor donor wafer is bonded to a receiver wafer which can be glass, plastic, metal or a metal compound, or semiconductor. It has been found that when a conductive layer, particularly a metal or metallic layer or a stack of such layers, is formed between the semiconductor donor wafer and the receiver wafer, these surfaces adhere readily, forming a good bond with little need for pressure, heat, plasma treatments, etc. to promote bonding. The conductive layer can be formed on either the donor wafer or the receiver wafer, or both, before affixing.

In a photovoltaic assembly including a receiver wafer and a semiconductor lamina with a conductive layer disposed between them, and a photovoltaic cell which comprises the lamina, the conductive layer also serves as an electrical contact, conducting photocurrent generated within the photovoltaic cell to circuitry outside the cell. If the conductive layer is reflective, and if it is formed on the back surface of the lamina when the photovoltaic cell is in operation, it may also serve as a reflector, reflecting light back into the lamina and improving efficiency.

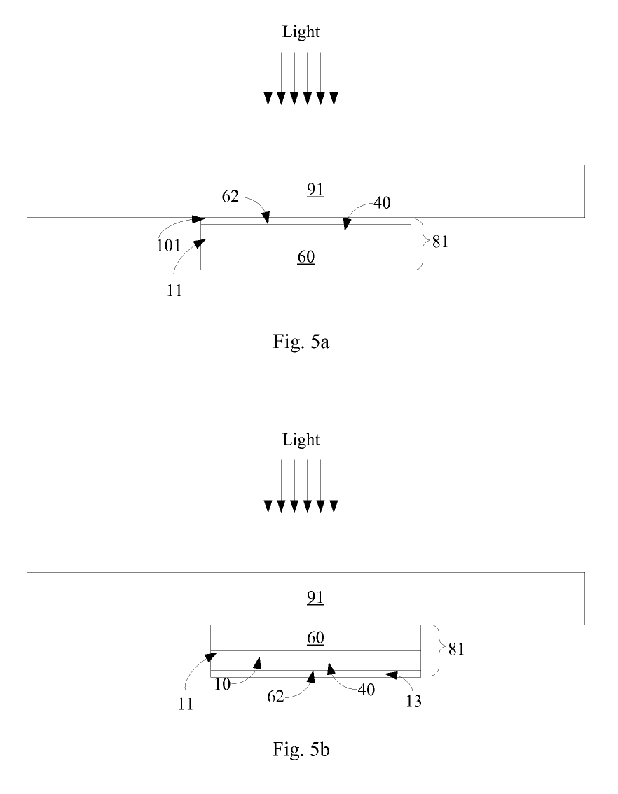

FIG. 4 illustrates photovoltaic assembly 80 including receiver wafer 60 and semiconductor lamina 40. Conductive layer 1 is disposed between receiver wafer 60 and semiconductor lamina 40. Photovoltaic assembly 80 is affixed to substrate 90. Substrate 90 will support, for example, 12, 36, or more photovoltaic assemblies 80 side-by-side to form a photovoltaic module. Conductive layer 11 may be, for example, titanium or aluminum, or other appropriate materials, as will be discussed. If titanium or aluminum was formed on the surface of either the donor wafer or receiver wafer 60 before the surfaces were affixed, high temperature during fabrication may have caused some or all of conductive layer 11 to react with the silicon of the donor wafer, forming a silicide. Photovoltaic assembly 80 comprises a photovoltaic cell. Light enters the cell at top surface 62. Conductive layer 11 serves as an adhesion layer, helping to bond semiconductor lamina 40 to receiver wafer 60. In this embodiment, lamina 40 comprises all or a portion of the base of a photovoltaic cell; thus photocurrent is generated within lamina 40. Conductive layer 11 also serves as an electrical contact, conducting photocurrent from lamina 40 to circuitry outside the cell (not shown). If conductive layer 11 is a reflective material like aluminum or titanium, it also serves to reflect light that has passed through the cell back into lamina 40, improving efficiency.

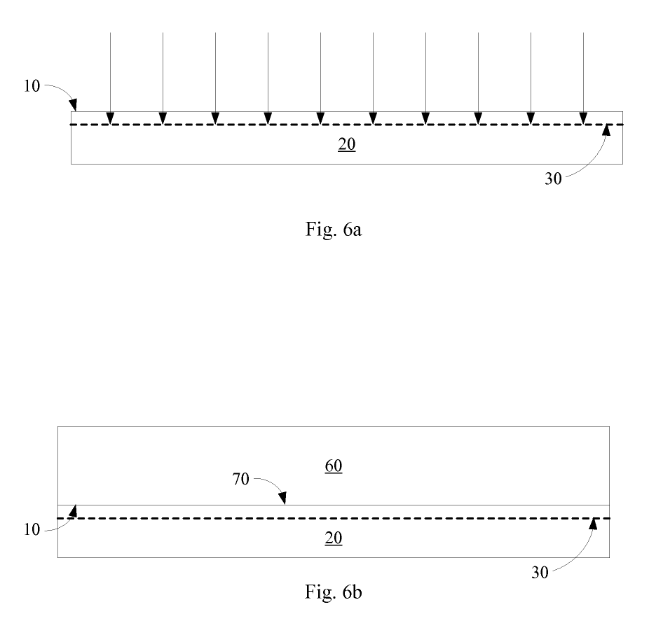

Alternatively, FIG. 5a illustrates another embodiment of the present invention. Conductive layer 11 is disposed between receiver wafer 60 and semiconductor lamina 40. Photovoltaic assembly 81 is affixed to superstrate 91, and comprises a photovoltaic cell. Superstrate 91 will support, for example, 12, 36, or more photovoltaic assemblies 81 side-by-side to form a photovoltaic module. As shown, in this embodiment, light passes through superstrate 91, through a transparent conductive oxide 101, and enters lamina 40 at second surface 62. Second surface 62 is the surface created by exfoliation of lamina 40. Conductive layer 11 serves as an adhesion layer, helping to bond semiconductor lamina 40 to receiver wafer 60, and as a reflective layer. In this embodiment, lamina 40 comprises all or a portion of the base of a photovoltaic cell; thus photocurrent is generated within lamina 40. Conductive layer 11 also serves as an electrical contact, conducting photocurrent from lamina 40 to circuitry outside the cell (not shown).

In another alternative embodiment, shown in FIG. 5b, if receiver element 60 and conductive layer 11 are transparent, photovoltaic assembly 81 may be inverted, such that light passes through superstrate 91, receiver wafer 60, conductive layer 11, then enters lamina 40 at first surface 10. A reflective layer 13, which can also serve as an electrical contact, is formed on second surface 62. Second surface 62 was created by exfoliation of lamina 40.

Summarizing, embodiments of the present invention include a photovoltaic assembly comprising: a semiconductor lamina having a lamina widest dimension; a receiver element having a receiver widest dimension, wherein the receiver widest dimension does not exceed the lamina widest dimension by more than about 50 percent; a continuous or discontinuous layer of conductive material disposed between the semiconductor lamina and the receiver; and a photovoltaic cell, wherein the photovoltaic cell comprises the semiconductor lamina. The layer of conductive material may comprise a metal and/or metal silicide. The receiver element is affixed to a substrate or superstrate, and the photovoltaic cell is electrically connected in series with other photovoltaic cells to form a photovoltaic module.

### Discussion: Implant and Exfoliation

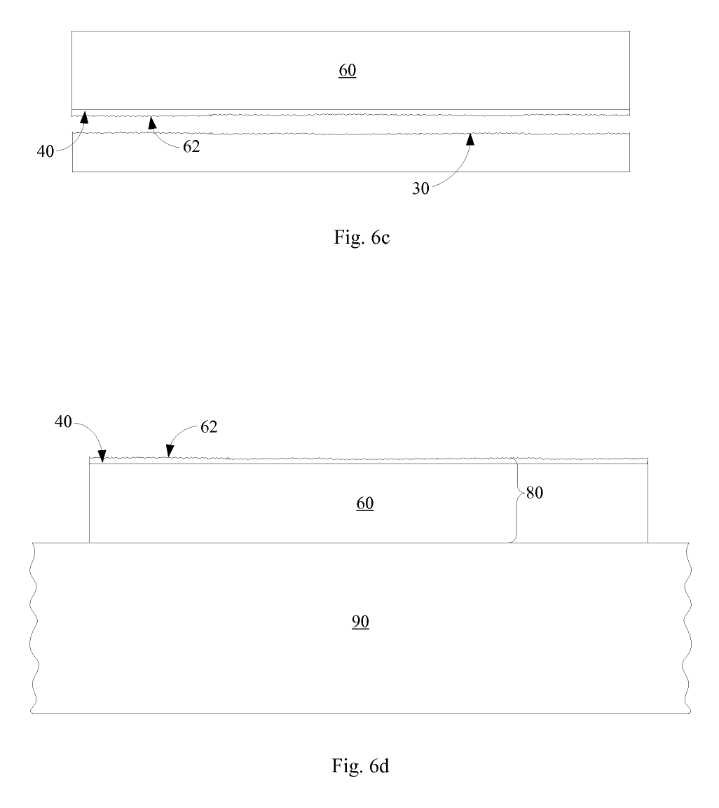

An effective way to cleave a thin lamina from a semiconductor donor body is by implanting gas ions into the semiconductor donor body to define a cleave plane, then to exfoliate the lamina along the cleave plane. Referring to FIG. 6a, one or more species of ions is implanted (indicated by arrows) through first surface 10 of wafer 20. A variety of gas ions may be used, including hydrogen and helium, singly or in combination. Each implanted ion will travel some depth below first surface 10. It will be slowed by electronic interactions and nuclear collisions with atoms as it travels through the lattice. The nuclear collisions may lead to displacement of the lattice atoms creating vacant lattice sites.

After implant, there will be a distribution both of ion depths and of lattice damage; there will be a maximum concentration in each distribution. The ion implantation step defines the cleave plane, and implant energy defines the depth of the cleave plane. It is preferred that the hydrogen implant is performed before the helium implant.

The depth of the implanted ions is determined by the energy at which the gas ions are implanted. At higher implant energies, ions travel farther, increasing the depth of the cleave plane. The depth of the cleave plane in turn determines the thickness of the lamina.

Preferred thicknesses for the lamina are between about 0.2 and about 100 microns; thus preferred implant energies for H+ range from between about 20 keV and about 10 MeV. Preferred implant energies for He+ ions to achieve these depths also range between about 20 keV and about 10 MeV.

As described by Agarwal et al. in “Efficient production of silicon-on-insulator films by co-implantation of He+ with H+”, American Institute of Physics, vol. 72, num. 9, pp. 1086-1088, March 1998, hereby incorporated by reference, it has been found that by implanting both H+ and He+ ions, the required dose for each can be significantly reduced. Decreasing dose decreases time and energy spent on implant, and may significantly reduce processing cost.

To form a lamina having a thickness of about 1 micron, implant energy for hydrogen should be about 100 keV; for a lamina of about 2 microns, about 200 keV, for a lamina of about 5 microns, about 500 keV, and for a lamina of about 10 microns, about 1000 keV. If hydrogen alone is implanted, the dose for a lamina of about 1 or about 2 microns will range between about 0.4×10¹⁷ and about 1.0×10¹⁷ ions/cm², while the dose for a lamina of about 5 or about 10 microns will range between about 0.4×10¹⁷ and about 2.0×10¹⁷ ions/cm².

If hydrogen and helium are implanted together, the dose for each is reduced compared to when either is implanted separately. When implanted with helium, hydrogen dose to form a lamina of about 1 or about 2 microns will be between about 0.1×10¹⁷ and about 0.3×10¹⁷ ions/cm², while to form a lamina of about 5 or about 10 microns hydrogen dose may be between about 0.1×10¹⁷ and about 0.5×10¹⁷ ions/cm².

When hydrogen and helium are implanted together, to form a lamina having a thickness of about 1 micron, implant energy for helium should be about 50 to about 200 keV; for a lamina of about 2 microns, about 100 to about 400 keV; for a lamina of about 5 microns, about 250 to about 1000 keV; and for a lamina of about 10 microns, about 500 keV to about 1000 keV. When implanted with hydrogen, helium dose to form a lamina of about 1 or about 2 microns may be about 0.1×10¹⁷ to about 0.3×10¹⁷ ions/cm², while to form a lamina of about 5 or about 10 microns, helium dose may be between about 0.1×10¹⁷ and about 0.5×10¹⁷ ions/cm². It will be understood that these are examples. Energies and doses may vary, and intermediate energies may be selected to form laminae of intermediate, lesser, or greater thicknesses.

Once ion implantation has been completed, further processing may be performed on wafer 20. Elevated temperature will induce exfoliation at cleave plane 30; thus until exfoliation is intended to take place, care should be taken, for example by limiting temperature and duration of thermal steps, to avoid inducing exfoliation prematurely. Once processing to first surface 10 has been completed, as shown in FIG. 6b, wafer 20 can be affixed to receiver wafer 60.

Turning to FIG. 6c, to induce exfoliation, receiver wafer 60 with affixed wafer 20 is subjected to elevated temperature, for example between about 200 and about 800 degrees C. Exfoliation proceeds more quickly at higher temperature. In some embodiments, the temperature step to induce exfoliation is performed at between about 200 and about 500 degrees C., with anneal time on the order of hours at 200 degrees C., and on the order of seconds at 500 degrees C. As temperature increases, bubbles or defects at the cleave plane begin to expand as the implanted gas atoms diffuse in all directions, forming micro-cracks. Eventually the micro-cracks merge and the pressure exerted by the expanding gas causes lamina 40 to separate entirely from the donor silicon wafer 20 along cleave plane 30. The presence of receiver wafer 60 forces the micro-cracks to expand sideways, forming a continuous split along cleave plane 30, rather than expanding perpendicularly to cleave plane 30 prematurely, which would lead to blistering and flaking at first surface 10.

FIG. 6d shows the structure inverted, with receiver wafer 60 on the bottom. First surface 10 of lamina 40 remains affixed to receiver wafer 60, and receiver wafer 60 is affixed to substrate 90.

For clarity, several examples of fabrication of a photovoltaic assembly including a lamina having thickness between 0.2 and 100 microns, where the lamina comprises, or is a portion of, a photovoltaic cell according to embodiments of the present invention, and a receiver wafer, where a conductive layer is disposed between the lamina and the receiver wafer, will be provided. For completeness, many materials, conditions, and steps will be described. It will be understood, however, that many of these details can be modified, augmented, or omitted while the results fall within the scope of the invention. In these embodiments, it is described to cleave a semiconductor lamina by implanting gas ions and exfoliating the lamina. Other methods of cleaving a lamina from a semiconductor wafer could also be employed in these embodiments.

### Example

### Standard Front-and-Back Contact Cell

The process begins with a donor body of an appropriate semiconductor material. An appropriate donor body may be a monocrystalline silicon wafer of any practical thickness, for example from about 300 to about 1000 microns thick. In alternative embodiments, the wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having crystals that are on the order of a millimeter in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline.

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with no unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

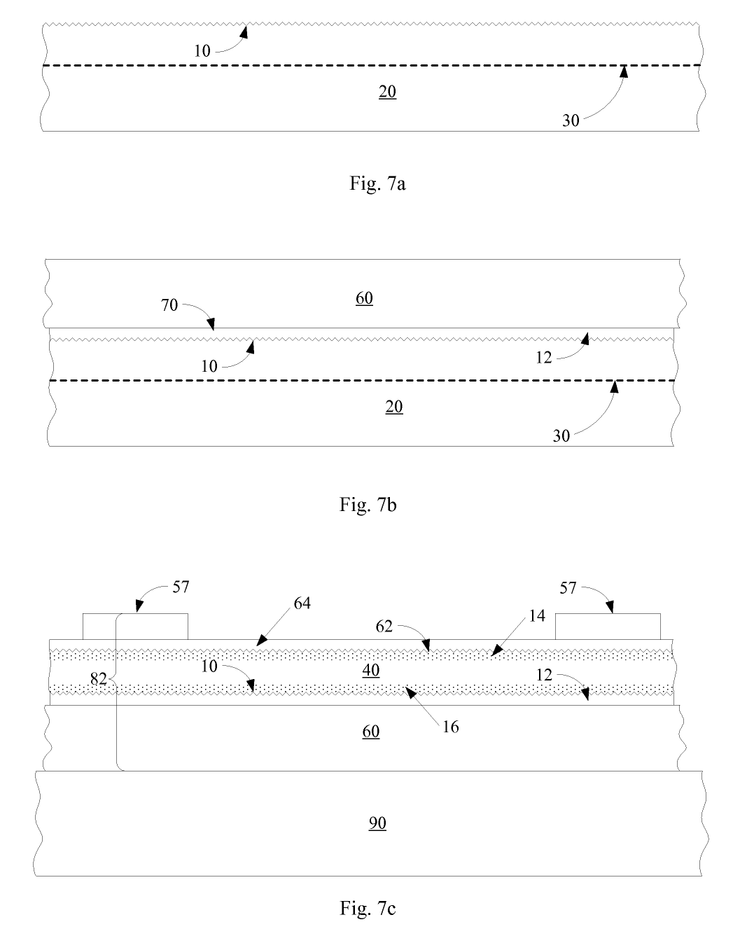

Referring to FIG. 7a, wafer 20 is formed of monocrystalline silicon which is preferably lightly doped to a first conductivity type. The present example will describe a relatively lightly p-doped wafer 20 but it will be understood that in this and other embodiments the dopant types can be reversed. Dopant concentration may be between about 1×10¹⁴ and 1×10¹⁸ atoms/cm³; for example between about 3×10¹⁴ and 1×10¹⁵ atoms/cm³; for example about 5×10¹⁴ atoms/cm³. Desirable resistivity for p-type silicon may be, for example, between about 133 and about 0.04 ohm-cm, preferably about 44 to about 13.5 ohm-cm, for example about 27 ohm-cm. For n-type silicon, desirable resistivity may be between about 44 and about 0.02 ohm-cm, preferably between about 15 and about 4.6 ohm-cm, for example about 9 ohm-cm.

First surface 10 is optionally treated to produce surface roughness, for example, to produce a Lambertian surface. The ultimate thickness of the lamina limits the achievable roughness. In conventional silicon wafers for photovoltaic cells, surface roughness, measured peak-to-valley, is on the order of one micron. In embodiments of the present invention, the thickness of the lamina may be between about 0.2 and about 100 microns. Preferred thicknesses include between about 1 and about 80 microns; for example, between about 1 and about 20 microns or between about 2 and about 20 microns. Practically, any thickness in the range between about 0.2 and about 100 microns is achievable; advantageous thicknesses may be between about 1 and about 1.5, 2, 3, 5, 8, 10, 20, or 50 microns.

If the final thickness is about 2 microns, clearly surface roughness cannot be on the order of microns. For all thicknesses, a lower limit of surface roughness would be about 500 angstroms. An upper limit would be about a quarter of the film thickness. For a lamina 1 micron thick, surface roughness may be between about 600 angstroms and about 2500 angstroms. For a lamina having a thickness of about 10 microns, surface roughness will be less than about 25000 angstroms, for example between about 600 angstroms and 25000 angstroms. For a lamina having a thickness of about 20 microns, surface roughness may be between about 600 angstroms and 50000 angstroms.

This surface roughness can be produced in a variety of ways which are well-known in the art. For example, a wet etch such as a KOH etch selectively attacks certain planes of the silicon crystal faster than others, producing a series of pyramids on a (100) oriented wafer, where the (111) planes are preferentially etched faster. A non-isotropic dry etch may be used to produce texture as well. Any other known methods may be used. The resulting texture is depicted in FIG. 7a. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001.

In some embodiments, diffusion doping may be performed at first surface 10. First surface 10 will be more heavily doped in the same conductivity type as original wafer 20, in this instance p-doped. Doping may be performed with any conventional p-type donor gas, for example B₂H₆ or BCl₃. In other embodiments, this diffusion doping step can be omitted.

Next ions, preferably hydrogen or a combination of hydrogen and helium, are implanted to define a cleave plane 30. Note that the plane of maximum distribution of implanted ions, and of implant damage, is conformal. Any irregularities at first surface 10 will be reproduced in cleave plane 30. Thus in some embodiments it may be preferred to texture surface 10 after the implant step rather than before.

After implant, first surface 10 is cleaned. Once the implant has been performed, exfoliation will occur once certain conditions, for example elevated temperature, are encountered. It is necessary, then, to keep processing temperature and duration below those which will initiate exfoliation until exfoliation is intended to take place.

Referring to FIG. 7b, donor wafer 20 is affixed to a receiver element, which may be wafer sized and will be called receiver wafer 60, at first surface 10. Receiver wafer 60 may be any appropriate material, such as semiconductor, glass, metal or metal compound, or high-temperature plastic. Receiver wafer 60 preferably is formed of a material that can tolerate relatively high temperature. For example, receiver wafer 60 may be borosilicate glass. In some embodiments, receiver wafer 60 may be float glass, and may be between about 200 and about 800 microns thick, for example between about 200 and about 400 microns thick.

A reflective, conductive metallic material, for example titanium or aluminum, preferably contacts first surface 10. In addition to titanium and aluminum, other alternatives for such a layer, in this and other embodiments, include chromium, molybdenum, tantalum, zirconium, vanadium, tungsten, nickel, copper, ruthenium, niobium, cobalt, zinc, indium, antimony, tin, lead, or iron, or any combination or alloys of any of these metals. This conductive layer can be any metal, metal compound, metal alloy, or metal silicide, or a combination of any of these. In some embodiments, it may be preferred to deposit a thin layer 12 of aluminum or titanium onto first surface 10. For example, aluminum can be sputter deposited onto first surface 10. Alternatively, receiving surface 70 of receiver wafer 60 may be coated with aluminum or some other reflective metallic material. In other embodiments, an aluminum layer can be formed on both first surface 10 and on receiving surface 70 of receiver wafer 60. In still other embodiments, this conductive layer can be a stack including two or more layers of different metals; for example this conductive layer may include a layer of titanium and a layer of aluminum.

In alternative embodiments, receiver wafer 60 can be a metal or metal alloy, such as titanium or aluminum. Pure aluminum has a relatively low melting temperature, so an aluminum alloy may be preferred, which may be coated with a thin layer of aluminum or titanium contacting donor wafer 20. Receiver wafer 60 may be formed of a relatively inexpensive and robust material, such as stainless steel, which may be coated with a reflective material which will contact first surface 10 of donor wafer 20. In this case, this reflective material also serves as a barrier between lamina 40 and the material of receiver wafer 60. If receiver wafer 60 is a metal or metal compound, its thickness will generally be at least 80 microns, for example between about 80 and about 500 microns, in some embodiments between about 100 and about 400 microns.

Donor wafer 20 can be any shape; common shapes are circular, square, and octagonal. It may be preferred for receiver wafer 60 to be substantially the same size and shape as donor wafer 20. Donor wafer 20 can be any size, though standard wafer sizes may be preferred, as standard equipment exists for handling them. Common wafer sizes are 100, 125, 150, 200, or 300 millimeters. In many embodiments, receiving surface 70 of receiver wafer 60 is slightly larger than first surface 10 of donor wafer 20, for example overlapping it on all sides by some millimeters. In most preferred embodiments, however, the widest dimension of receiver wafer 60 will not exceed the widest dimension of donor wafer 20 by more than 50 percent; in other embodiments, the widest dimension of receiver wafer 60 will not exceed the widest dimension of donor wafer 20 by more than about 10 percent or about 20 percent. In other embodiments, receiver wafer 60 may have a different shape than donor wafer 20. For example, receiver wafer 60 may be square, while donor wafer 20 is an octagon that fits within the area of the square.

First surface 10 of donor wafer 20 and receiving surface 70 of receiver wafer 60 are to be adhered with a bond sufficiently secure to survive subsequent processing, eventual assembly into a photovoltaic module, and transport and operation of the finished photovoltaic module. It has been found that inclusion of conductive layer 12 between these surfaces tends to promote bonding between them. For example, in some embodiments layer 12 is a layer of titanium formed on first surface 10 of donor wafer 20, where layer 12 may be between about 30 angstroms and about 2000 angstroms thick, for example about 150 angstroms thick, and receiver wafer 60 is, for example, borosilicate glass. The silicon of donor wafer 20 is in immediate contact with layer 12. Both surfaces to be bonded are preferably cleaned, for example by a megasonic clean with water to remove any particles. A native oxide may have formed on titanium layer 12 before the surfaces are contacted. A strong bond forms when first surface 10 of donor wafer 20, which is coated with titanium layer 12, is aligned and contacted to receiving surface 70 of receiver wafer 60 and subjected to very modest pressure at very modest temperature. In other embodiments, however, higher pressure may be used. Pressure may be between about 100 pascals and about 10 megapascals, for example about 300 pascals and about 0.4 megapascals, for example about 300 pascals. For example, pressure may be less than about 0.4 megapascals. Temperature may range between room temperature and about 400 degrees C.

Turning to FIG. 7c, lamina 40 can now be cleaved from donor wafer 20 at cleave plane 30 as described earlier. Second surface 62 has been created by exfoliation. In FIG. 7c, the structure is shown inverted, with receiver wafer 60 on the bottom. As has been described, some surface roughness is desirable to increase light trapping within lamina 40 and improve conversion efficiency of the photovoltaic cell. The exfoliation process itself creates some surface roughness at second surface 62. In some embodiments, this roughness may alone be sufficient. In other embodiments, surface roughness of second surface 62 may be modified or increased by some other known process, such as a wet or dry etch, as may have been used to roughen first surface 10. If metal 12 is a p-type acceptor such as aluminum, annealing to the Al—Si eutectic temperature at this point or later will serve to form or additionally dope p-doped region 16.

Next a region 14 at the top of lamina 40 is doped through second surface 62 to a conductivity type opposite the conductivity type of the original wafer 20. In this example, original wafer 20 was lightly p-doped, so doped region 14 will be n-type. This doping may be performed by any conventional means. In preferred embodiments this doping step is performed by diffusion doping using any appropriate donor gas that will provide an n-type dopant, for example POCl₃.

Diffusion doping is typically performed at relatively high temperature, for example between about 700 and about 1000 degrees C., although lower temperature methods, such as plasma enhanced diffusion doping, can be performed instead. This elevated temperature will cause some aluminum from aluminum layer 12 to diffuse in at first surface 10 and become a p-type acceptor. This elevated temperature can serve as the anneal mentioned earlier to form a more heavily doped p-type region 16 which will serve to form a good electrical contact to aluminum layer 12. If doping of p-region 16 from aluminum layer 12 is sufficient, the earlier diffusion doping step performed at first surface 10 to form this region can be omitted. If oxygen is present during the n-type diffusion doping step, a thin layer of oxide (not shown) will form at second surface 62.

Edge-trimming may be performed by any conventional method, in this and other embodiments, to remove any electrical connection formed between n-doped region 14 and p-doped region 16 during this doping step.

Antireflective layer 64 is preferably formed, for example by deposition or growth, on second surface 62. Incident light enters lamina 40 through second surface 62; thus layer 64 should be transparent. In some embodiments antireflective layer 64 is silicon nitride, which has a refractive index of about 1.5 to 3.0; its thickness would be, for example, between about 500 and 2000 angstroms, for example about 650 angstroms.

Next wiring 57 is formed on layer 64. In some embodiments, this wiring is formed by screen printing conductive paste in the pattern of wiring, which is then fired at high temperature, for example between about 700 and about 900 degrees C. For example, if layer 64 is silicon nitride, it is known to screen print wiring using screen print paste containing silver. During firing, some of the silver diffuses through the silicon nitride, effectively forming a via through the insulating silicon nitride 64, making electrical contact to n-doped silicon region 14. Contact can be made to the silver remaining above antireflective layer 64. A completed photovoltaic assembly 82 is shown in FIG. 7c.

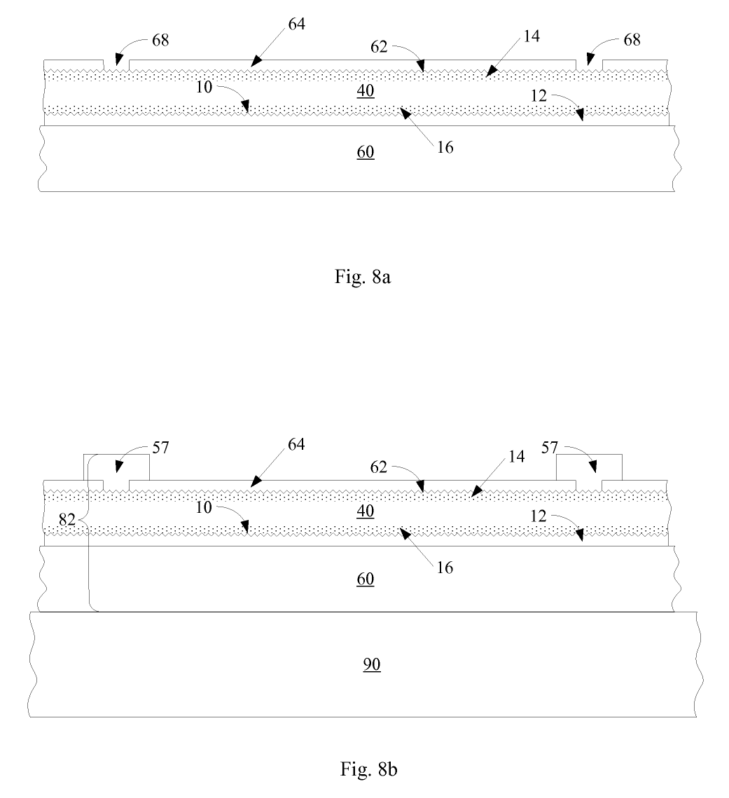

In an alternative embodiment, shown in FIG. 8a, instead of forming silver screen print wiring 57 on intact silicon nitride layer 64, a series of parallel trenches 68 are formed in silicon nitride layer 64, exposing the silicon of second surface 62 in each trench 68. Trenches 68 can be formed by any appropriate method, for example by photolithographic masking and etching. Optionally, a second diffusion doping step with an n-type dopant can be performed at this point, more heavily doping silicon exposed in trenches 68.

FIG. 8b shows wiring 57, which is formed contacting n-doped region 14 exposed in the trenches. Wiring 57 can be formed by any convention means. It may be preferred to form a metal layer on silicon nitride layer 64, then form wiring 57 from the metal layer by photolithographic masking and etching. In an alternate embodiment, wiring 57 is formed by screen printing, for example to form aluminum wiring. Aluminum screen print paste can be fired at a lower temperature than the temperature required to diffuse silver from the silver paste through silicon nitride. Reducing processing temperature may be advantageous.

FIGS. 7c and 8b both show completed photovoltaic assembly 82 according to two embodiment of the present invention. In each, photovoltaic assembly 82 comprises lamina 40 and receiver wafer 60, and comprises a photovoltaic cell. Note that the lightly p-doped body of lamina 40 is the base of this cell, while heavily doped n-region 14 is the emitter; thus lamina 40 comprises a photovoltaic cell. Current is generated within lamina 40 when it is exposed to light. Electrical contact is made to both first surface 10 and second surface 62 of this cell. A conductive layer, aluminum layer 12, intervenes between semiconductor lamina 40 and receiver wafer 60. During operation, after passing through semiconductor lamina 40, some or all light is reflected from aluminum layer 12 back into lamina 40. Layer 12 is substantially continuous.

Referring to FIG. 7c or 8b, in embodiments in which receiver wafer 60 is formed of a transparent material such as glass, if conductive layer 12 is not perfectly reflective, some light may pass through conductive layer 12, and then continue through transparent receiver wafer 60. In these embodiments, it may be preferred to form a second reflective layer (not shown) on the back surface of receiver wafer 60, between it and substrate 90. This second reflective layer, which may be formed of aluminum or some other reflective material, serves to reflect light back through receiver wafer 60 and into lamina 40.

A plurality of photovoltaic assemblies 82 is fabricated. Each is inspected for flaws, and the assemblies are tested, and may be sorted by performance. Photovoltaic assemblies are then selected from the plurality based on results of the testing step, assembled onto a substrate 90, and electrically connected to form a completed photovoltaic module. In alternative embodiments, photovoltaic assemblies 82 could be affixed to a transparent superstrate (not shown).

### Example

### Amorphous Emitter and Base Contacts

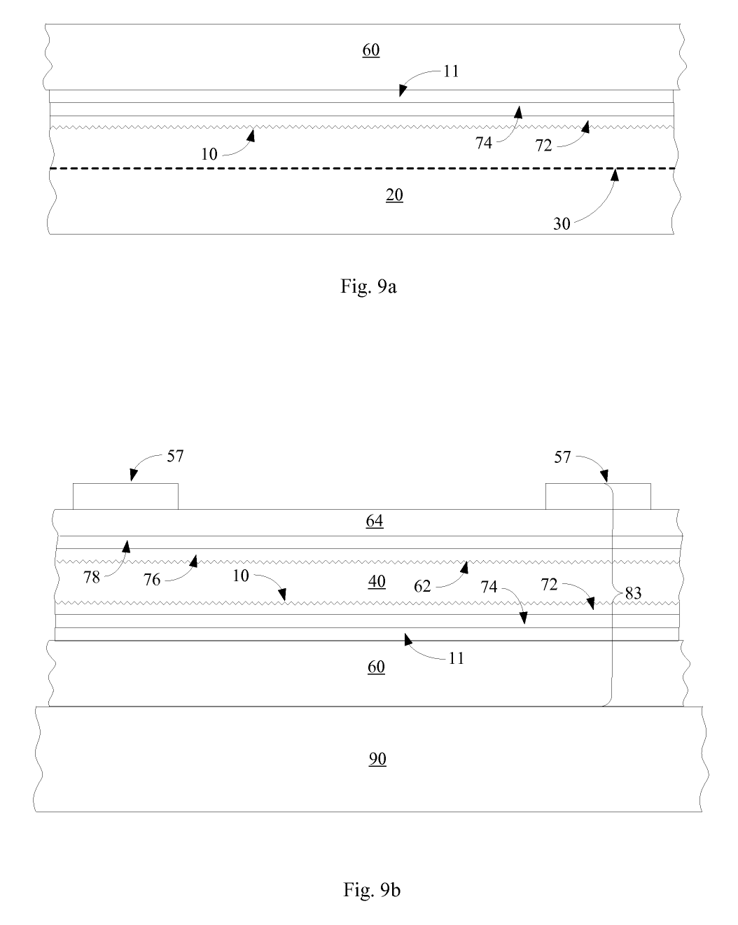

In another embodiment, one or both heavily doped regions of the cell are formed in amorphous semiconductor layers. Turning to FIG. 9a, to form this cell, in one embodiment, donor body 20 is a lightly n-doped silicon wafer (as always, in alternate embodiments, conductivity types can be reversed.) First surface 10 of wafer 20 is optionally roughened as in prior embodiments. After cleaning first surface 10, a layer 72 of intrinsic (undoped) amorphous silicon is deposited on first surface 10, followed by a layer 74 of n-doped amorphous silicon by any suitable method, for example by plasma enhanced chemical vapor deposition (PECVD). The combined thickness of amorphous layers 72 and 74 may be between about 200 and about 500 angstroms, for example about 350 angstroms. In one embodiment, intrinsic layer 72 is about 50 angstroms thick, while n-type amorphous layer 74 is about 300 angstroms thick. Gas ions are implanted through layers 74, 72 and into first surface 10 to define cleave plane 30 as in prior embodiments. It will be understood that the implant energy must be adjusted to compensate for the added thickness of amorphous layers 74 and 72.

A reflective, conductive material 11 is formed on n-doped layer 74, on receiver element 60, or both, as in prior embodiments, and donor wafer 20 is affixed to receiver element 60 at first surface 10, with intrinsic layer 72, n-doped layer 74, and conductive layer 11 intervening between them. Receiver element 60 may be about the size of a conventional silicon wafer, and may be called a receiver wafer. Conductive layer 11 can be aluminum, titanium, or any other suitable material. Receiver wafer 60 can be any suitable material, for example borosilicate glass, stainless steel, titanium, aluminum or aluminum alloy, etc., which may or may not be coated, for example with aluminum or titanium. Preferably after a megasonic clean of both bonding surfaces, donor wafer 20 and receiver wafer 60 are bonded using known wafer bonding techniques, for example, including the bonding conditions noted earlier. As noted, the presence of conductive layer 11 between donor wafer 20 and receiver wafer 60 aids in bonding, which may be achieved with minimal bonding temperature and pressure.

FIG. 9b shows the structure inverted, with receiver wafer 60 at the bottom. Lamina 40 is exfoliated from wafer 20 along cleave plane 30, creating second surface 62. Second surface 62 is optionally roughened, and is cleaned. Intrinsic amorphous silicon layer 76 is deposited on second surface 62, followed by p-doped amorphous silicon layer 78. The thicknesses of intrinsic amorphous layer 76 and p-doped amorphous layer 78 may be about the same as intrinsic amorphous layer 72 and n-doped amorphous layer 74, respectively, or may be different. Next antireflective layer 64, which may be, for example, silicon nitride, is formed on p-type amorphous layer 78 by any suitable method. In alternative embodiments, antireflective layer 64 may be a transparent conductive oxide (TCO). If this layer is a TCO, it may be, for example, of indium tin oxide, tin oxide, titanium oxide, zinc oxide, etc. A TCO will serve as both a top electrode and an antireflective layer and may be between about 500 and 1500 angstroms thick, for example, about 900 angstroms thick.

Finally wiring 57 is formed on antireflective layer 64. Wiring 57 can be formed by any appropriate method. In a preferred embodiment, wiring 57 is formed by screen printing.

FIG. 9b shows completed photovoltaic assembly 83, which includes lamina 40 and receiver wafer 60. Photovoltaic assembly 83 comprises a photovoltaic cell. In this embodiment, lamina 40 is the base, or a portion of the base, of the photovoltaic cell. Heavily doped p-type amorphous layer 78 is the emitter, or a portion of the emitter. Amorphous layer 76 is intrinsic, but in practice, amorphous silicon will include defects that cause it to behave as if slightly n-type or slightly p-type. If it behaves as if slightly p-type, then, amorphous layer 76 will function as part of the emitter, while if it behaves as if slightly n-type, it will function as part of the base.

In this embodiment, conductive layer 11 serves as an adhesion layer during bonding, as an electric contact to conduct photocurrent generated within the lamina to circuitry (not shown) on the photovoltaic module, and as a reflective layer.

As in prior embodiments, a plurality of such photovoltaic assemblies 83 will be fabricated, and each will be inspected for defects and tested for performance and sorted. Photovoltaic assemblies will be selected to be affixed to a substrate 90, electrically connected in series, and fabricated into a completed photovoltaic module. In alternative embodiments, photovoltaic assemblies 83 could be affixed to a transparent superstrate (not shown).

### Example

### Exfoliated Surface as Back Surface

In the embodiments so far described, the cell was fabricated such that the first surface of the lamina, the original surface of the donor body, is the back surface of the finished cell, and the second surface created by exfoliation is the front surface, where light enters the cell. An embodiment will be described in which the lamina is exfoliated to a transparent receiver element where light travels through the receiver element. In this embodiment, the original surface of the donor body, affixed to the receiver element, is the front surface where light enters the cell, while the second surface, created by exfoliation, is the back surface of the finished cell.

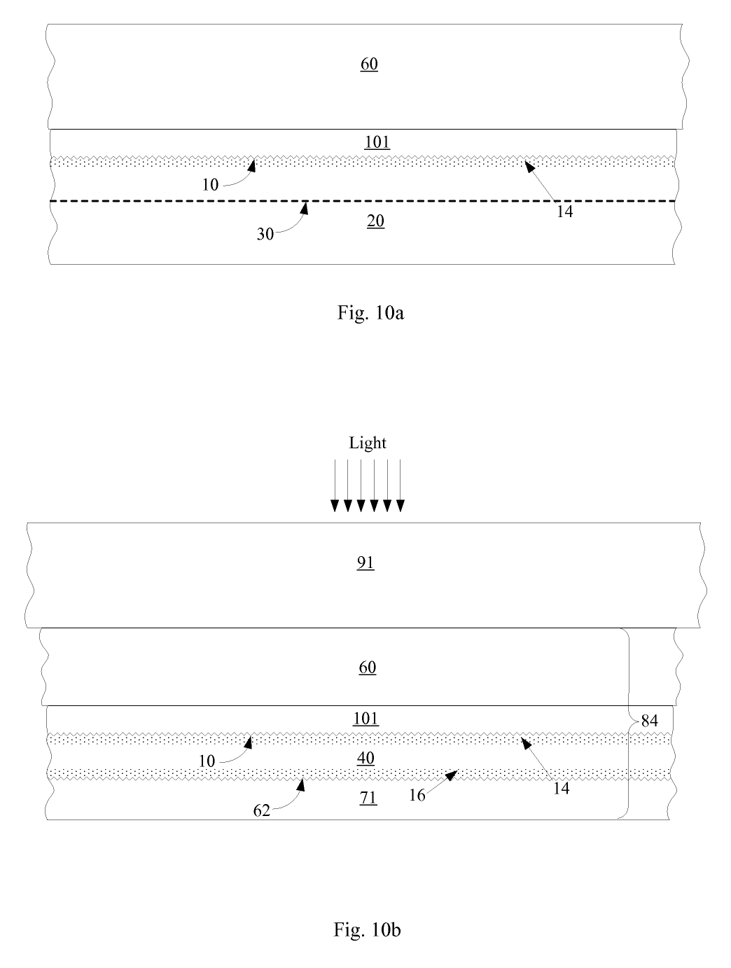

Turning to FIG. 10a, in this example semiconductor donor body 20 is a lightly p-doped silicon wafer. First surface 10 of wafer 20 is optionally textured as in prior embodiments. Next a doping step, for example by diffusion doping, forms n-doped region 14. If oxygen is present during this doping step, a thin oxide (not shown) will grow at first surface 10. It will be understood that, as in all embodiments, conductivity types can be reversed. Gas ions are implanted through first surface 10 to define cleave plane 30.

First surface 10 is cleaned, removing any oxide formed during diffusion doping. In the present example, TCO 101 is between first surface 10 and receiver element or wafer 60. This TCO 101 is indium tin oxide, titanium oxide, zinc oxide, or any other appropriate material, and can be deposited on first surface 10, on receiver wafer 60, or both. As TCO 101 serves as both a contact and as an antireflective coating, its thickness should be between about 500 and about 1500 angstroms thick, for example about 900 angstroms thick. Wafer 20 is affixed to receiver wafer 60 at first surface 10, and wafer 20 and receiver wafer 60 are bonded, for example using conventional wafer bonding techniques. Note receiver wafer 60 is a transparent material such as borosilicate glass.

Turning to FIG. 10b, lamina 40 is exfoliated from wafer 20 at cleave plane 30, creating second surface 62. Second surface 62 is optionally textured. Conductive layer 71 is deposited on second surface 62. Conductive layer 71 is preferably a metal, for example aluminum. If conductive layer 71 is aluminum, an anneal forms p-doped layer 16. If some other material is used for conductive layer 71, p-doped layer 16 must be formed by a diffusion doping step before conductive layer 71 is formed. Aluminum layer 71 can be formed by many methods, for example by sputtering. Note that in this embodiment, a conductive layer, TCO 101, intervenes between lamina 40 and receiver wafer 60.

As in prior embodiments, photovoltaic assemblies are fabricated, then each is inspected and tested. A photovoltaic module is formed by affixing a plurality of photovoltaic assemblies to a superstrate 91. FIG. 10b shows the completed photovoltaic assembly 84 affixed to superstrate 91 in a completed photovoltaic module. Incident light falls on superstrate 91, and is transmitted through superstrate 91, receiver wafer 60, and TCO 101 before entering the photovoltaic cell at second surface 62. Lamina 40 comprises both the base and emitter of the photovoltaic cell. In an alternative embodiment, photovoltaic assemblies 84 can be affixed to a substrate.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

1. A photovoltaic assembly comprising:
a semiconductor lamina having a lamina widest dimension;
a receiver element having a receiver widest dimension, wherein the receiver widest dimension does not exceed the lamina widest dimension by more than about 50 percent;
a continuous or discontinuous layer of conductive material disposed between the semiconductor lamina and the receiver; and
a photovoltaic cell, wherein the photovoltaic cell comprises the semiconductor lamina.

2. The photovoltaic assembly of claim 1 wherein the semiconductor lamina has a thickness between about 1 and about 50 microns.

3. The photovoltaic assembly of claim 1 wherein the conductive material comprises a metal, metal compound, metal alloy, and/or metal silicide.

4. The photovoltaic assembly of claim 3 wherein the conductive material comprises titanium and/or titanium silicide.

5. The photovoltaic assembly of claim 3 wherein the conductive material comprises aluminum.

6. The photovoltaic assembly of claim 1 wherein the layer of conductive material is substantially continuous and, during operation of the photovoltaic cell, after passing through the semiconductor lamina, some or all light is reflected from the layer of conductive material back into the semiconductor lamina.

7. The photovoltaic assembly of claim 1 wherein, during operation of the photovoltaic cell, photocurrent flows from the semiconductor lamina through the layer of conductive material to circuitry on a photovoltaic module.

8. The photovoltaic assembly of claim 1 wherein the receiver element comprises metal or metal compound, glass, or plastic.

9. The photovoltaic assembly of claim 1 wherein the semiconductor lamina comprises substantially crystalline silicon.

10. A method for forming a photovoltaic cell, the method comprising:
affixing a first surface of a semiconductor donor body to a receiving surface of a receiver element wherein a conductive layer is disposed between the first surface and the receiving surface,
wherein the semiconductor donor body has a donor widest dimension, and the receiver element has a receiver widest dimension, wherein the receiver widest dimension does not exceed the donor widest dimension by more than fifty percent; and
cleaving a semiconductor lamina from the semiconductor donor body at a cleave plane wherein the semiconductor lamina remains affixed to the receiver element,
wherein the photovoltaic cell comprises the semiconductor lamina.

11. The method of claim 10 wherein the semiconductor donor body is a substantially crystalline silicon wafer.

12. The method of claim 11 wherein the semiconductor donor body is a monocrystalline silicon wafer.

13. The method of claim 10 wherein the receiver element comprises glass, metal, metal compound, or plastic.

14. The method of claim 13 wherein the receiver element comprises stainless steel.

15. The method of claim 10 wherein the conductive layer is formed on the first surface of the semiconductor donor body before the affixing step.

16. The method of claim 10 wherein the conductive layer is formed on the receiving surface of the receiver element before the affixing step.

17. A method for forming a photovoltaic assembly comprising a photovoltaic cell, the method comprising:
implanting one or more species of gas ions through a first surface of a semiconductor donor body to define a cleave plane;
affixing the first surface of the semiconductor donor body to a receiving surface of a receiver element, wherein the first surface of the semiconductor donor body is in immediate contact with a conductive layer, wherein the semiconductor donor body has a donor widest dimension, and the receiver element has a receiver widest dimension, wherein the receiver widest dimension does not exceed the donor widest dimension by more than fifty percent;
cleaving a semiconductor lamina from the semiconductor donor body, wherein the semiconductor lamina remains affixed to the receiver element; and
fabricating the photovoltaic cell, wherein the photovoltaic cell comprises the semiconductor lamina,
and wherein the photovoltaic assembly comprises the receiver element and the semiconductor lamina.

18. The method of claim 17 wherein the conductive layer comprises titanium, titanium silicide, or a titanium alloy.

19. The method of claim 17 wherein the conductive layer comprises aluminum, aluminum silicide, or an aluminum alloy.

20. The method of claim 17 wherein the conductive layer is a transparent conductive oxide.

21. The method of claim 17 wherein the conductive layer is formed on the first surface of the semiconductor donor body before the affixing step.

22. The method of claim 17 wherein the semiconductor lamina comprises substantially crystalline silicon.

23. The method of claim 17 further comprising either:
affixing the photovoltaic assembly to a substrate or affixing the photovoltaic assembly to a superstrate; and
electrically connecting the photovoltaic cell in series with other photovoltaic cells to form a photovoltaic module.

24. A photovoltaic assembly comprising:
a semiconductor lamina having a lamina widest dimension;
a receiver element having a receiver widest dimension, wherein the receiver widest dimension does not exceed the lamina widest dimension by more than about 50 percent;
a layer of metal, metal compound, metal alloy, or metal silicide disposed between the semiconductor lamina and the receiver; and
a photovoltaic cell, wherein the photovoltaic cell comprises the semiconductor lamina.

25. The photovoltaic assembly of claim 24 wherein the metal, metal compound, metal alloy, or metal silicide is titanium or titanium silicide.
